(19) United States
(12) Patent Application Publication
(10) Pub. No.: US 2014/0216925 A1
(43) Pub. Date: Aug. 7, 2014

(54) Single Target Sputtering of Copper Zinc Tin Sulfide Selenide, CZT(S, Se)

(71) Applicants: Jason D. Myers, Alexandria, VA (US); Jesse A. Frantz, Landover, MD (US); Robel Y. Bekele, Washington, DC (US); Jasbinder S. Sanghera, Ashburn, VA (US); Vinh Q. Nguyen, Fairfax, VA (US)

(72) Inventors: Jason D. Myers, Alexandria, VA (US); Jesse A. Frantz, Landover, MD (US); Robel Y. Bekele, Washington, DC (US); Jasbinder S. Sanghera, Ashburn, VA (US); Vinh Q. Nguyen, Fairfax, VA (US)

(21) Appl. No.: 13/756,730

(22) Filed: Feb. 1, 2013

(51) Int. Cl. C23C 14/34

(52) U.S. Cl. CPC C23C 14/34
USPC 204/192.28; 204/192.1

(57) ABSTRACT

A method of forming a CZT(S,Se) thin film from a quaternary target involves sputtering a quaternary target onto a substrate, wherein the quaternary target comprises (a) copper, (b) zinc, (c) tin, and (d) selenium and/or sulfur, wherein each component (a) through (d) is present in the quaternary target within ±50% of a 2:1:1:4 molar ratio, respectively, thereby forming a CZT(S,Se) thin film on the substrate, wherein the CZT(S,Se) thin film has a kesterite crystalline phase and a band gap of about 1.0 to 1.5 eV. In an embodiment, a ternary target is employed.

### BACKGROUND

The current industry standard thin film inorganic photovoltaic materials, CuInₓGa₁₋ₓSe₂ (0≦x≦1) (CIGS) and CdTe, are ultimately limited in their energy production capacity by the abundance of Te, In, and, to a lesser extent, Ga. Therefore, materials with a greater abundance are highly desirable.

The copper-zinc-tin-chalcogenide kesterites, Cu₂ZnSnS₄ and Cu₂ZnSnSe₄, also termed Cu₂ZnSn(S,Se)₄ or CZT(S,Se) are the most promising of what are dubbed the “earth-abundant” thin film photovoltaic materials, with efficiency of 10.1% from a hydrazine-processed slurry (see reference 1). Vacuum-based deposition methods have also yielded efficient devices, with a current record of 9.15% using a multi-stage thermal evaporation approach (see reference 2). Many other approaches have been used to form the absorbed layer, including multi-step sputtering of elemental or binary precursors, pulsed laser deposition, and electrodeposition (see references 3-8). These prior art approaches suffer from various deficiencies: co-evaporation is difficult to control; layer-by-layer sulfurization/selenization requires numerous steps; and formation using liquid nanoparticles uses hydrazine which is flammable, toxic, and can be dangerously unstable.

Regardless of the deposition technique, there are two primary challenges in forming CZT(S,Se). The first is maintaining proper stoichiometry of the film, as Zn, Sn, and (S,Se) have high vapor pressures and can be lost during high temperature processing: deviations from the desired stoichiometry in the final film causes poor photovoltaic properties. Secondly, the proper kesterite crystalline phase must be formed to achieve the desired 1-1.5 eV band gap; other phases can form which have lower band gaps.

A need exists for improved methods for generation of thin films of CZT(S,Se), particularly for use in photovoltaic applications.

### BRIEF SUMMARY

In one embodiment, a method of forming a CZT(S,Se) thin film from a quaternary target involves sputtering a quaternary target onto a substrate, wherein the quaternary target comprises (a) copper, (b) zinc, (c) tin, and (d) selenium and/or sulfur, wherein each component (a) through (d) is present in the quaternary target within ±50% of a 2:1:1:4 molar ratio, respectively, thereby forming a CZT(S,Se) thin film on the substrate, wherein the CZT(S,Se) thin film has a kesterite crystalline phase and a band gap of about 1.0 to 1.5 eV.

In another embodiment, a method of forming a CZT(S,Se) thin film from a ternary target(s) involves sputtering a ternary target onto a substrate, wherein the ternary target consists of three components selected from (a) copper, (b) zinc, (c) tin, and/or (d) selenium and/or sulfur, wherein each component (a) through (d) that is present in the ternary target occurs therein within ±50% of a 2:1:1:4 molar ratio, respectively, thereby forming a CZT(S,Se) thin film on the substrate, wherein the CZT(S,Se) thin film has a kesterite crystalline phase and a band gap of about 1.0 to 1.5 eV.

### BRIEF DESCRIPTION OF THE DRAWINGS

FIG. 1 is an image of an exemplary quaternary target ready for sputtering.

FIG. 2 is a top-down electron microscope image of a CZTSe film.

FIG. 3 is cross section electron microscope image of a CZTSe film.

### DETAILED DESCRIPTION

Definitions

Before describing the present invention in detail, it is to be understood that the terminology used in the specification is for the purpose of describing particular embodiments, and is not necessarily intended to be limiting. Although many methods, structures and materials similar, modified, or equivalent to those described herein can be used in the practice of the present invention without undue experimentation, the preferred methods, structures and materials are described herein. In describing and claiming the present invention, the following terminology will be used in accordance with the definitions set out below.

As used herein, the term “CZT(S,Se)” refers to the copper-zinc-tin-chalcogenide materials Cu₂ZnSnS₄ and Cu₂ZnSnSe₄, including combinations thereof, and including materials wherein the elements are present within ±50% of the nominal 2:1:1:4 molar ratio.

As used in this specification and the appended claims, the singular forms “a”, “an,” and “the” do not preclude plural referents, unless the content clearly dictates otherwise.

As used herein, the term “and/or” includes any and all combinations of one or more of the associated listed items.

As used herein, the term “about” when used in conjunction with a stated numerical value or range denotes somewhat more or somewhat less than the stated value or range, to within a range of ±20% of that stated.

Description

Disclosed herein is technique for fabricating a sputtering target with a desired stoichiometry and subsequently forming a thin CZT(S,Se) film through single-step quaternary sputtering for use in a photovoltaic device.

This approach is an improvement over other vacuum deposition techniques. First, pre-synthesis of CZT(S,Se) enables precise stoichiometric control and target homogeneity. Second, films sputtered from the pre-synthesized target can be produced with a preferred stoichiometry (by adjusting the stoichiometry of the sputtering target) without the need for post-processing treatments (annealing and sulfurization/selenization), a significant advantage over other deposition techniques. The resulting thin film has a composition that is more reproducible than that formed by prior art methods. Quaternary sputtering is a simpler and more economical deposition technique than existing vacuum deposition methods, such as multi-target sputtering and thermal evaporation.

Typically, CZT(S,Se) with desired stoichiometry will be prepared by heating in elements in the desired proportions an ampule, then grinding the CZT(S,Se) into a powder. The CZT(S,Se) powder may be hot pressed into a puck, then machined into the desired final target dimensions suitable for deposition by sputtering, for example RF sputtering, DC sputtering, or pulsed DC sputtering.

In forming the target, it is possible to employ elemental Cu, Zn, Sn, and Se/S, and/or compounds thereof such as Cu₂S, ZnS, SnS₂, or their selenide analogues. A combination of these can be added to a quartz ampoule and reacted to form CZT(S,Se). It is also possible to reduce the number of steps required to fabricate the target by forming it directly during the initial CZT(S,Se) formation by using an appropriately-shaped ampoule, negating the need for grinding and hot pressing.

Non-stoichiometric quantities of each element can be added to create an off-stoichiometric CZT(S,Se) compound, i.e. copper-poor or tin-rich compounds. In one embodiment, the target is formed that is relatively rich in Zn, Sn, and/or (S,Se) in order to account for relative loss of such elements during processing, thus achieving a CZT(S,Se) thin film having the desired stoichiometry.

Instead of a single target, multiple ternary or quaternary targets, preferably with differing stoichiometries can be used. Use of multiple targets of differing stoichiometry is expected provide varied stoichiometry throughout the active layer.

### EXAMPLE

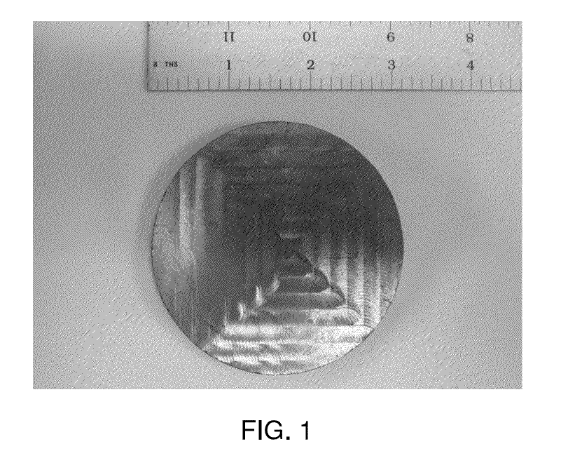

Elemental copper, zinc, tin and selenium were combined in a 2:1:1:4 molar ratio and sealed inside a quartz ampoule. The ampoule was then heated gradually to 750° C. and held at temperature for 30 hours to form CZTSe. The ampoule was then broken and the CZTSe is ground to a fine powder using a mortar and pestle. The powder was then placed in a hot press for one hour at 650° C. with a 10-ton ram force to form a compressed target that was subsequently machined to 3″ diameter by ⅛″ thick as seen in FIG. 1. A ruler measured in inches (2.54 cm) is also shown for scale). The target was indium-bonded to a copper backing plate prior to installation in a sputter deposition system.

To form films, deposition was carried out onto a molybdenum-coated soda lime glass substrate, where the molybdenum served as the bottom electrode (anode) of the photovoltaic device. CZTSe was deposited onto the substrate using RF magnetron sputtering in a sputter-up geometry in an Ar atmosphere at a pressure of 1-5 mT with an energy density on the order of 0.5-2 W/cm2 with the substrate held at ˜500° C. The nominal thickness of the deposited CZTSe layer was 500-2000 nm. The substrate was rotated at ˜10 rpm during deposition. After CZTSe deposition, CdS, a transparent conducting oxide of ZnO/Aluminum-doped ZnO, and nickel/aluminum grids were deposited to finish the device in accordance with standard industry practice.

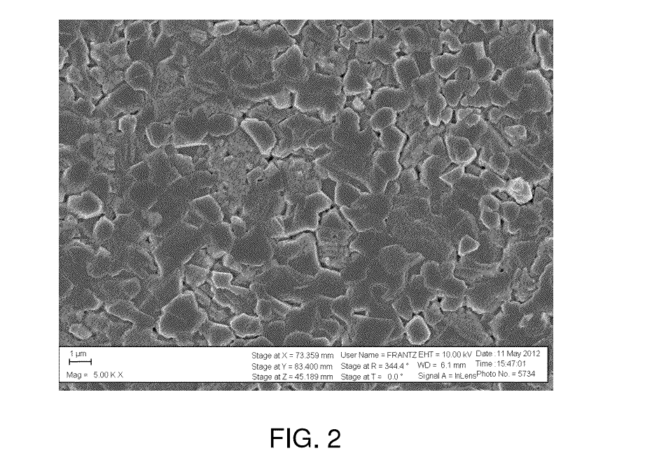

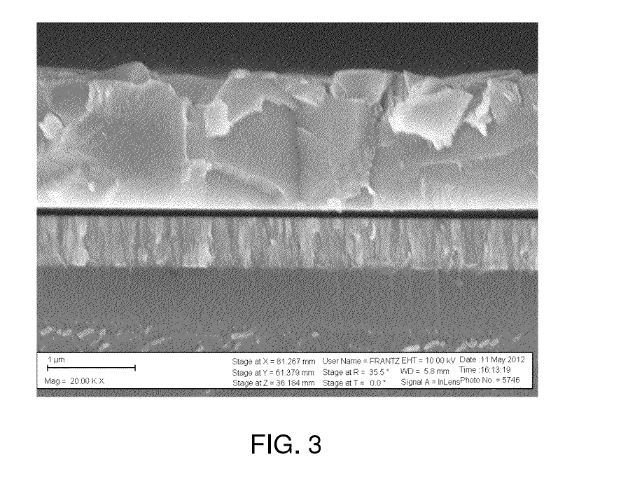

FIGS. 2 and 3 show top-down and cross section electron microscope images, respectively, of the resulting CZTSe film.

### CONCLUDING REMARKS

All documents mentioned herein are hereby incorporated by reference for the purpose of disclosing and describing the particular materials and methodologies for which the document was cited.

Although the present invention has been described in connection with preferred embodiments thereof, it will be appreciated by those skilled in the art that additions, deletions, modifications, and substitutions not specifically described may be made without departing from the spirit and scope of the invention. Terminology used herein should not be construed as being “means-plus-function” language unless the term “means” is expressly used in association therewith.

### REFERENCES

[1] D. A. R. Barkhouse, O. Gunawan, T. Gokmen, T. K. Todorov, and D. B. Mitzi, “Device characteristics of a 10.1% hydrazine-processed Cu₂ZnSn(Se,S)₄ solar cell,” Prog. Photovolt: Res. Appl.
[2] I. Repins, C. Beall, N. Vora, C. DeHart, D. Kuciauskas, P. Dippo, B. To, J. Mann, W.-C. Hsu, A. Goodrich, and R. Noufi, “Co-evaporated Cu₂ZnSnSe₄ films and devices,” Solar Energy Materials and Solar Cells, vol. 101, no. 0, pp. 154-159, June 2012.
[3] S. M. Pawar, B. S. Pawar, A. V. Moholkar, D. S. Choi, J. H. Yun, J. H. Moon, S. S. Kolekar, and J. H. Kim, “Single step electrosynthesis of Cu₂ZnSnS₄ (CZTS) thin films for solar cell application,” Electrochimica Acta, vol. 55, no. 12, pp. 4057-4061, April 2010.

[4] R. Schurr, A. Holzing, S. Jost, R. Hock, T. Voβ, J. Schulze, A. Kirbs, A. Ennaoui, M. Lux-Steiner, A. Weber, I. Kötschau, and H.-W. Schock, “The crystallisation of Cu₂ZnSnS₄ thin film solar cell absorbers from co-electroplated Cu—Zn—Sn precursors,” Thin Solid Films, vol. 517, no. 7, pp. 2465-2468, February 2009.

[5] H. Katagiri, N. Sasaguchi, S. Hando, S. Hoshino, J. Ohashi, and T. Yokota, “Preparation and evaluation of Cu₂ZnSnS₄ thin films by sulfurization of E-B evaporated precursors,” Sol. Energy Mater. Sol. Cells, vol. 49, no. 1-4, pp. 407-414, December 1997.

[6] H. Katagiri, K. Jimbo, S. Yamada, T. Kamimura, W. S. Maw, T. Fukano, T. Ito, and T. Motohiro, “Enhanced Conversion Efficiencies of Cu₂ZnSnS₄-Based Thin Film Solar Cells by Using Preferential Etching Technique,” Appl. Phys. Lett., vol. 1, p. 041201, April 2008.
[7] T. Tanaka, T. Nagatomo, D. Kawasaki, M. Nishio, Q. Guo, A. Wakahara, A. Yoshida, and H. Ogawa, “Preparation of Cu₂ZnSnS₄ thin films by hybrid sputtering,” Journal of Physics and Chemistry of Solids, vol. 66, no. 11, pp. 1978-1981, November 2005.

[8] A. V. Moholkar, S. S. Shinde, A. R. Babar, K.-U. Sim, Y. Kwon, K. Y. Rajpure, P. S. Patil, C. H. Bhosale, and J. H. Kim, “Development of CZTS thin films solar cells by pulsed laser deposition: Influence of pulse repetition rate,” Sol. Energy, vol. 85, no. 7, pp. 1354-1363, July 2011.

What is claimed is:

1. A method of forming a CZT(S,Se) thin film from a quaternary target, the method comprising:
sputtering a quaternary target onto a substrate, wherein the quaternary target comprises (a) copper, (b) zinc, (c) tin, and (d) selenium and/or sulfur, wherein each component (a) through (d) is present in the quaternary target within ±50% of a 2:1:1:4 molar ratio, respectively,
thereby forming a CZT(S,Se) thin film on the substrate, wherein the CZT(S,Se) thin film has a kesterite crystalline phase and a band gap of about 1.0 to 1.5 eV.

2. The method of claim 1, wherein the CZT(S,Se) thin film comprises each said component (a) through (d) within ±20% of a 2:1:1:4 molar ratio, respectively.

3. The method of claim 1, wherein the deposition is performed using RF or DC sputtering.

4. The method of claim 1, further comprising preparing the quaternary target by heating elemental copper, zinc, tin, and selenium and/or sulfur to at least 700° C.

5. The method of claim 1, further comprising depositing a transparent conducting oxide of ZnO/Aluminum-doped ZnO onto the CZT(S,Se) thin film.

6. The method of claim 5, wherein the depositing the transparent conducting oxide is done without performing annealing, sulfurization, or selenization on the CZT(S,Se) thin film.

7. The method of claim 1, further comprising forming the ternary target by combining and heating selected elements and/or compounds.

8. A method of forming a CZT(S,Se) thin film from a ternary target, the method comprising:
sputtering a ternary target onto a substrate, wherein the ternary target consists of three components selected from (a) copper, (b) zinc, (c) tin, and/or (d) selenium and/or sulfur, wherein each component (a) through (d) that is present in the ternary target occurs therein within ±50% of a 2:1:1:4 molar ratio, respectively,
thereby forming a CZT(S,Se) thin film on the substrate, wherein the CZT(S,Se) thin film has a kesterite crystalline phase and a band gap of about 1.0 to 1.5 eV.

9. The method of claim 8, wherein each said component (a) through (d) that is present in the CZT(S,Se) thin film occurs therein within ±20% of a 2:1:1:4 molar ratio, respectively.

10. The method of claim 8, wherein the deposition is performed using either RF or DC sputtering.

11. The method of claim 8, further comprising preparing the quaternary target by heating elemental copper, zinc, tin, and selenium and/or sulfur to at least 700° C.

12. The method of claim 8, further comprising depositing a transparent conducting oxide of ZnO/Aluminum-doped ZnO onto the CZT(S,Se) thin film

13. The method of claim 12, wherein the depositing the transparent conducting oxide is done without performing annealing, sulfurization, or selenization on the CZT(S,Se) thin film.

14. The method of claim 8, further comprising forming the ternary target by combining and heating selected elements and/or compounds.
